(19) United States
(12) Patent Application Publication
(10) Pub. No.: US 2003/0164523 A1
(43) Pub. Date: Sep. 4, 2003

(54) Semiconductor circuit arrangement and a method for producing same

(76) Inventors: Christian Herzum, Poecking (DE); Ulrich Krumbein, Rosenheim (DE); Karl-Heinz Muller, Velden (DE)

Correspondence Address: SCHIFF HARDIN & WAITE, 6600 SEARS TOWER, 233 S WACKER DR, CHICAGO, IL, 60606-6473, US

(21) Appl. No.: 10/148,240

(22) PCT Filed: Nov. 30, 2000
(86) PCT No.: PCT/EP00/12050

(51) Int. Cl. H01L 29/76

(52) U.S. Cl. 257/365

(57) ABSTRACT

The invention relates to a semiconductor circuit arrangement comprising a circuit element that is embodied in a semiconductor substrate (1) of a first conductivity type in an integrated manner and is provided with at least one gate electrode (G1, G2) and a first (D) and a second electrode connection (S). According to the invention, the at least one gate electrode is at least partially silicated on the side thereof facing away from the main surface of the semiconductor substrate.

The invention relates to a semiconductor circuit arrangement having a circuit element which is formed in an integrated manner in a semiconductor substrate of a first conductivity type and has at least one control terminal and a first and second electrode terminal, and also to a method for fabricating such a semiconductor circuit arrangement.

Known examples of such semiconductor circuit arrangements are MOS tetrodes and MOS pentodes having a plurality of control terminals, in particular having at least two gate terminals, namely a high-frequency gate and at least one control gate, which are produced either as individual components or in highly integrated form on a semiconductor substrate by means of VLSI technology steps (VLSI=very large scale integration). A suitability for supply voltages of 12 V or more is demanded in particular when such MOS tetrodes are used in automotive engineering. The modern CMOS process production methods are generally only designed for the production of semiconductor circuits for supply voltages of ≦5 V and are not readily suitable for the production of semiconductor circuits with higher supply voltage ranges. Essential technological reasons for this include, inter alia, the excessively small gate oxide thickness and an excessively low drain-well breakdown voltage in the semiconductor circuits produced in modern standard CMOS processes, which circuits are therefore not readily suitable for the production of MOS tetrodes and MOS pentodes with supply voltages of 12 V or more.

Moreover, the high-frequency behavior of such MOS tetrodes and MOS pentodes is important, primarily the electrical resistance of the gate terminals, in particular of the high-frequency gate, being problematic since the resistance noise is amplified in the high-frequency gate in the tetrode and the noise quality of the component is thus determined. In addition, the high-frequency gain that can be achieved decreases as the gate resistance increases. In order to obtain a minimum gate resistance, the processes used for MOS tetrodes without exception use metal gates whose sheet resistance, with a typical value of about Rₛ=40 mΩ/, in orders of magnitude lower than in the poly-gates that are usually used in CMOS processes and have typical sheet resistances of around Rₛ=20 to 150 Ω/.

The invention is based on the object of providing a semiconductor circuit arrangement, in particular one having a plurality of control terminals, namely at least two gate terminals, one of which is a high-frequency gate, such as in the case of tetrodes of pentodes, which have a gate resistance of the control terminals with a low order of magnitude comparable to that usually achieved in the case of metal gates, and also of specifying a method for fabricating such a semiconductor circuit arrangement which can be carried out in a simple manner.

The object is achieved by means of the method specified in claim 1 and the semiconductor circuit arrangement specified in claim 11.

According to the invention, it is provided that the at least one control terminal, preferably produced from polysilicon, is siliconized at least in regions on its side remote from the main surface of the semiconductor substrate. In order to reduce the sheet resistance, the invention proposes siliconizing the control terminals made of polysilicon, whereby a comparable noise figure compared with prior-art metal-gate technology can be obtained. Experiments have shown that the noise is significantly worse if the control terminals or gates made of polysilicon are not siliconized. When TiSi is used for the siliconization, it is possible to obtain sheet resistances Rₛ of about 3 Ω/.

In a development of the invention, it may be provided that the first electrode terminal or drain terminal is spared from the siliconization. In principle, the gate, source, intermediate and drain regions are siliconized simultaneously by the self-aligning silicide process according to the invention. It has been found, however, that siliconized drain terminals have a less favorable strength with respect to electrostatic discharges (ESD strength; ESD=electrostatic discharge). In particular in those applications in which the semiconductor circuit arrangement according to the invention, in particular tetrode or pentode, is used as a discrete component or as a so-called I/O transistor in an integrated circuit, and where it is feared that siliconized drains lead to an inadequate ESD strength, the drain regions should be spared from the siliconization.

In a preferred embodiment of the invention it may be provided that the at least one control terminal is only partly siliconized. As a result of the remaining siliconized part of the control terminal, the control terminal overall acquires a sufficiently low resistance. In this case, the non-siliconized part of the control terminal may have an extent of about 0.2 μm to about 0.8 μm, in particular 0.4 μm given a minimum length of the control terminal of about 0.6 μm to about 3.0 μm, in particular 1.4 μm.

Furthermore, it may be possible for the control gate not to be siliconized at all, and the intermediate region between the gate nearest the drain terminal and the gate directly adjacent thereto to be partly siliconized.

On the other hand, it is equally possible, following the principle of the invention, to achieve a sufficient ESD strength if the first electrode terminal or drain terminal is only partly siliconized and the distance between the siliconized region of the electrode terminal (drain terminal) and the associated contacts is chosen to be large enough.

Preferred developments of the invention emerge from the further subclaims.

Further features, advantages and expediencies of the invention emerge from the following description of exemplary embodiments of the invention with reference to the drawing, in which:

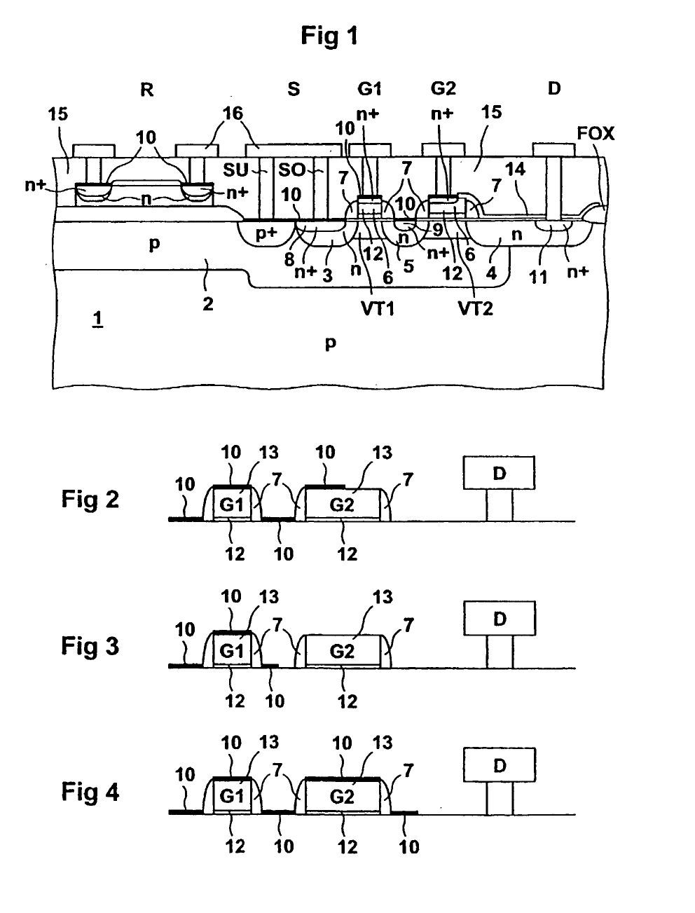

FIG. 1 shows a diagrammatic sectional view of a preferred exemplary embodiment of the invention;

FIG. 2 shows a diagrammatic sectional view of an exemplary embodiment of the invention in which the second gate is partly siliconized;

FIG. 3 shows a diagrammatic sectional view of an exemplary embodiment of the invention in which the second gate is completely excluded from the siliconization; and

FIG. 4 shows a diagrammatic sectional view of an exemplary embodiment of the invention in which the drain region is partly siliconized.

The semiconductor circuit arrangement shown in FIG. 1 comprises a high-frequency MOS tetrode as circuit element of an integrated semiconductor circuit according to the particularly preferred exemplary embodiment of the invention. It is fabricated according to a standard CMOS process method which is assumed to be known, with a semiconductor substrate 1 made of p-conducting silicon (p-type doping=first conductivity type according to this definition), the circuit element formed in an integrated manner having at least two control terminals made of polysilicon 6 on gate dielectrics 12, namely a high-frequency gate G1 with a channel region VT1 and a control gate G2—isolated by the intermediate region—with a channel region VT2, and also a first electrode terminal, namely a drain terminal D, and a second electrode terminal, namely source terminal S (comprising source So and substrate terminal Su). The channel regions VT1 and VT2 arranged below the poly-gates G1 and G2 may be doped differently by different channel implantations, that is to say may also be, for instance, respectively n- or p-doped A p-type region 2 formed in the substrate 1 by doping serves as p-type well and the p+-type region embedded therein serves as substrate terminal. The reference numerals 3, 4 and 5 designate lightly doped n-LDD regions (LDD=lightly doped drain) in each case in source, drain and intermediate regions. Spacers 7 made of a suitable dielectric are formed laterally beside the gates G1 and G2; the reference numerals 8, 9, 11 designate n+-doped contact regions in the source terminal S, drain terminal D, and also in the intermediate region between the two gates, the contact regions 8, 9 and 11, as can be seen in the illustration, in each case from source S and intermediate region being isolated from the relevant gate or channel by the spacer 7. A larger distance between gate G2 or channel and drain terminal D is set by a suitable setting by means of a mask. The gate terminals G1 and G2 are partly or else completely implanted with n+-type doping. The p-type well 2 ends in the region between the gate G2 and the n+-doped contact region 11 of the drain terminal D. R designates a high-resistance resistor.

After the completion of the insulation (FOX=field oxide), the p-type well, the channel regions, the gates, the LDD terminal regions, the spacers on the sidewalls of the gate fingers, the n+-type and p+-type regions by means of method steps known per se (see e.g. Widmann, “Technologie hochintegrierter Schaltungen” [Technology of large scale integrated circuits], Springer Verlag, 2nd edition, page 5 et seq), a self-aligned silicide layer is produced. To that end, a TEOS-SiO2 layer 14 (TEOS=tetraethyl orthosilicate) is applied by the LPCVD method (LPCVD=low pressure chemical vapor deposition) and patterned by means of a resist mask and etching. This defines the regions for the subsequent siliconization process. After the application of a thin titanium layer by means of sputtering (cathode ray sputtering), rapid thermal annealing (RTA) is carried out to effect a first siliconization, i.e. conversion of titanium and silicon into titanium silicide TiSi 10 at the locations at which titanium is in contact with silicon. Remaining, i.e. unconverted, titanium residues are removed by a subsequent etching process. By means of a further RTA process step (second siliconization), the titanium silicide layer is converted from a high-resistance phase (C49) into a low-resistance phase (C54). Two steps are required for the siliconization operation since, in the first step, it is not permitted to use temperatures as high as are actually required in order to obtain a good, i.e. low-resistance, titanium silicide. If excessively high temperatures were used, there is the risk of the titanium already reacting with the silicon of the SiO2 and this leading to conductive connections between silicon regions to be insulated. As a result, the process would no longer be self-aligning. High temperatures are allowed in the second siliconization process since titanium is then no longer situated on the SiO2 The deposition of a premetal dielectric 15 follows, and further process steps that are customary in standard CMOS processes.

Furthermore, it may be possible for the control gate not to be siliconized at all, and for the intermediate region between the gate nearest the drain terminal and the gate directly adjacent thereto to be partly siliconized.

On the other hand, it is equally possible, following the principle of the invention, to achieve a sufficient ESD strength if the first electrode terminal or drain terminal is only partly siliconized and the distance between the siliconized region of the electrode terminal (drain terminal) and the associated contacts is chosen to be large enough.

The basic variants of the gate siliconization according to the invention are illustrated again in FIGS. 2, 3 and 4, in enlarged sectional illustrations, only the silicide regions 10, gate dielectric 12, gate-poly 13 and spacers 7 being shown in FIGS. 2, 3 and 4 for reasons of better illustration.

The exemplary embodiment according to FIG. 2 corresponds to the example illustrated in detail according to FIG. 1, so that reference can be made to the explanations in respect of the latter. In this case, the at least one control terminal G2 is only partly siliconized. As a result of the remaining, siliconized part of the control terminal, the control terminal G2 overall acquires a sufficiently low resistance. The non-siliconized part of the control terminal may have an extent of about 0.2 μm to about 0.8 μm, in particular 0.4 μm given a minimum length of the control terminal of about 0.6 μm to about 3.0 μm, in particular 1.4 μm.

In the exemplary embodiment according to FIG. 3, the intermediate region between G1 and G2 is partly siliconized. Control terminal G2 and drain are not siliconized. However, this embodiment is impaired relative to the particularly preferred exemplary embodiment according to FIG. 2 since a lack of siliconization of gate G2 leads to performance losses.

In the exemplary embodiment according to FIG. 4, the drain region is partly siliconized. In this case, it is possible to obtain a sufficient ESD strength only when the distance between the siliconized region of the drain terminal and the drain contact is chosen to be large enough.

### List of Reference Symbols

1 Semiconductor substrate

2 p-type region

3, 4, 5 Lightly doped n-LDD regions

6 Polysilicon

7 Spacers

8, 9, 11 n+-doped contact regions

10 Silicide regions

12 Gate dielectric

13 Gate-poly

14 TEOS-SiO2 layer

Gi High-frequency gate

G2 Control gate

D Drain terminal

S Source terminal

VT1, VT2 Channel regions

1. A method for fabricating a semiconductor circuit arrangement having a circuit element which is formed in an integrated manner in a semiconductor substrate (1) of a first conductivity type and has at least one control terminal (G1, G2) and also a first (D) and second electrode terminal (S), characterized
in that the at least one control terminal is siliconized at least in regions on its side remote from the main surface of the semiconductor substrate.

2. The method as claimed in claim 1, characterized
in that the first electrode terminal (D) is spared from the siliconization.

3. The method as claimed in claims 1 and 2, characterized
in that the first electrode terminal (D) is at most partly siliconized.

4. The method as claimed in claims 1 to 3, characterized
in that the at least one control terminal (G2) is only partly siliconized.

5. The method as claimed in claims 1 to 4, characterized
in that the semiconductor circuit arrangement has two control terminals (G1, G2) arranged adjacent, and one of the control terminals is completely siliconized and the other control terminal is not siliconized or is siliconized only in regions.

6. The method as claimed in claims 1 to 5, characterized
in that the siliconization of the at least one control terminal and/or of the at least one electrode terminal is effected by means of a self-aligning salicide method.

7. The method as claimed in claims 1 to 6, characterized
in that the siliconization is carried out by means of titanium silicon (TiSi), tungsten silicon (WSi) or another comparable, metal-containing silicon compound exhibiting high temperature stability.

8. The method as claimed in claims 1 to 7, characterized
in that the at least one control terminal comprises polysilicon.

9. The method as claimed in claims 1 to 8, characterized
in that the semiconductor circuit arrangement is formed as a discrete component with at least two control terminals.

10. The method as claimed in claims 1 to 9, characterized
in that the semiconductor circuit arrangement constitutes a high-frequency transistor with at least two control terminals.

11. A semiconductor circuit arrangement having a circuit element which is formed in an integrated manner in a semiconductor substrate (1) of a first conductivity type and has at least one control terminal (G1, G2) and also a first (D) and second electrode terminal (S), characterized
in that the at least one control terminal is siliconized at least in regions on its side remote from the main surface of the semiconductor substrate.

12. The semiconductor circuit arrangement as claimed in claim 11, characterized
in that the first electrode terminal (D) is spared from the siliconization.

13. The semiconductor circuit arrangement as claimed in claim 11 or 12, characterized
in that the first electrode terminal (D) is at most partly siliconized.

14. The semiconductor circuit arrangement as claimed in claims 11 to 14, characterized
in that the at least one control terminal (G2) is only partly siliconized.

15. The semiconductor circuit arrangement as claimed in claims 11 to 14, characterized
in that the semiconductor circuit arrangement has two control terminals (G1, G2) arranged adjacent, and one of the control terminals is completely siliconized and the other control terminal is not siliconized or is siliconized only in regions.

16. The semiconductor circuit arrangement as claimed in claims 11 to 15, characterized
in that the siliconization of the at least one control terminal and/or of the at least one electrode terminal is effected by means of a self-aligning salicide method.

17. The semiconductor circuit arrangement as claimed in claims 11 to 16, characterized
in that the siliconization is carried out by means of titanium silicon (TiSi), tungsten silicon (WSi) or another comparable, metal-containing silicon compound exhibiting high temperature stability.

18. The semiconductor circuit arrangement as claimed in claims 11 to 17, characterized
in that the at least one control terminal comprises polysilicon.

19. The semiconductor circuit arrangement as claimed in claims 11 to 18, characterized
in that the semiconductor circuit arrangement is formed as a discrete component with at least two control terminals.

20. The semiconductor circuit arrangement as claimed in claims 11 to 19, characterized
in that the semiconductor circuit arrangement constitutes a high-frequency transistor with at least two control terminals.
